(19) United States
(12) Patent Application Publication
(10) Pub. No.: US 2010/0164021 A1
(43) Pub. Date: Jul. 1, 2010

(54) METHOD OF MANUFACTURING SEMICONDUCTOR DEVICE

(76) Inventor: Yong-Soo Cho, Gangnam-gu (KR)

Correspondence Address: SHERR & VAUGHN, PLLC, 620 HERNDON PARKWAY, SUITE 320, HERNDON, VA, 20170, US

(21) Appl. No.: 12/640,945

(22) Filed: Dec. 17, 2009

(30) Foreign Application Priority Data
Dec. 30, 2008 (KR) 10-2008-0136199

(51) Int. Cl. H01L 29/78; H01L 21/336; H01L 21/64

(52) U.S. Cl. 257/408; 438/305; 29/25.01; 257/E21.433; 257/E29.266

(57) ABSTRACT

A method of manufacturing a semiconductor device may include implanting fluorine ions into a portion of a poly gate region on a semiconductor substrate; forming a gate oxide film over the semiconductor substrate such that the gate oxide film is thicker in the fluorine-implanted region; forming the poly gate over the gate oxide film in the poly gate region; and forming lightly doped drains in active regions of the semiconductor substrate on both sides of the poly gate. Further, the method of manufacturing the semiconductor device includes forming spacers over both sidewalls of the poly gate; and forming source and drain regions in the active regions.

The present application claims priority under 35 U.S.C. 119 to Korean Patent Application No. 10-2008-0136199 (filed on Dec. 30, 2009), which is hereby incorporated by reference in its entirety.

### BACKGROUND

In a CMOS (Complementary MOS) process for mobile products, a 4.3-V power pad with a 3.3-V MOSFET device for I/O of CMOS logic products may be used. When a 4.3-V power pad is used with a 3.3-V I/O MOSFET device, it is important to ensure HCI (Hot Carrier Injection) reliability. However, a high electric field is formed at the edge of the gate facing the drain, which makes it difficult to ensure HCI reliability. When HCI reliability is not ensured, device reliability may deteriorate due to hot carrier characteristics, sub-threshold voltage characteristics, leakage current, gate induced drain leakage (GIDL), and punchthrough characteristics, caused by the thickness and quality of a gate oxide film at the edge of the gate of the MOSFET.

### SUMMARY

Embodiments relate to a method of manufacturing a semiconductor device. In particular, embodiments relate to a method of manufacturing a semiconductor device in which fluorine ions are implanted into a part of a region on the semiconductor substrate where a gate is to be formed such that a dual gate oxide film over a drain has a relatively large thickness, thereby reducing an electric field applied to the drain and improving HCI (Hot Carrier Injection) reliability when a 4.3-V power pad with a 3.3-V MOSFET (Metal Oxide Semiconductor Field Effect Transistor) is used.

Embodiments provide a method of manufacturing a semiconductor device which may include implanting fluorine ions into a portion of a poly gate region on a semiconductor substrate; forming a gate oxide film over the semiconductor substrate such that the gate oxide film is thicker in the fluorine-implanted region; forming the poly gate over the gate oxide film in the poly gate region; forming lightly doped drains in active regions of the semiconductor substrate on both sides of the poly gate; forming spacers over both sidewalls of the poly gate; and forming source and drain regions in the active regions.

Embodiments relate to a semiconductor device which may include a semiconductor substrate including a fluorine-implanted region overlapping a poly gate region. An oxide film may be formed over a fluorine-implanted semiconductor substrate such that a gate oxide film has a relatively large thickness over the fluorine-implanted region. A poly gate may be formed in the poly gate region over the gate oxide film. Lightly doped drains may be formed in active regions of the semiconductor substrate on the sides of the poly gate. Spacers may be formed over both sidewalls of the poly gate. Source and drain regions may be formed in the active regions.

Embodiments relate to an apparatus configured to: implant fluorine ions into a portion of a poly gate region on a semiconductor substrate; form a gate oxide film over the semiconductor substrate such that the gate oxide film is thicker in the fluorine-implanted region; form the poly gate over the gate oxide film in the poly gate region; form lightly doped drains in active regions of the semiconductor substrate on both sides of the poly gate; form spacers over both sidewalls of the poly gate; and form source and drain regions in the active regions.

With the method of manufacturing a semiconductor device according to embodiments, fluorine ions are implanted into a part of a region on the semiconductor substrate where the gate is to be formed such that a dual gate oxide film over a drain is formed so as to have a relatively large thickness. Thus, an electric field applied to the drain can be reduced, and HCI reliability can be improved when a 4.3-V power pad with a 3.3-V MOSFET is used. Further, fluorine ions are implanted so as to form a dual gate oxide film below a gate region. Therefore, it is not necessary to perform an additional mask process for forming a dual gate oxide film, and to simplify a process for forming a dual gate oxide film.

### DRAWINGS

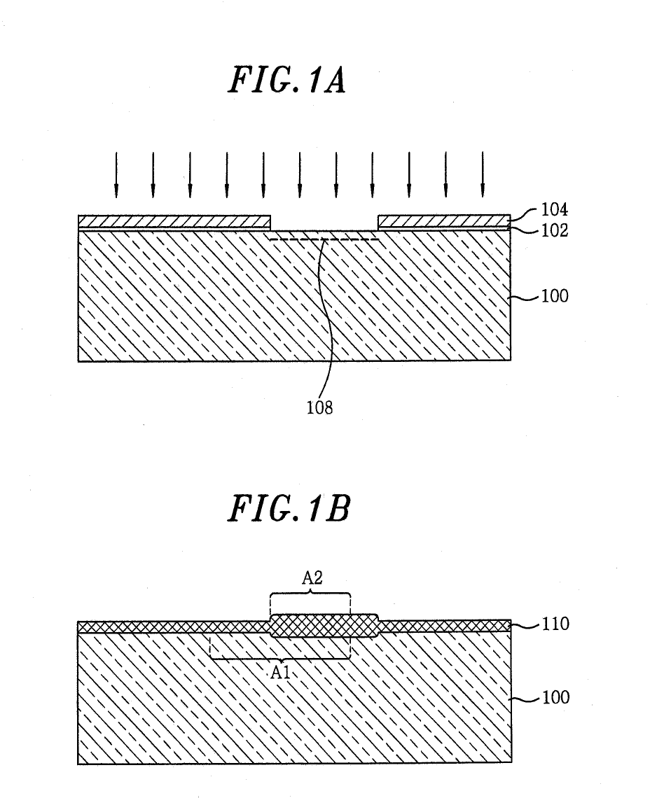

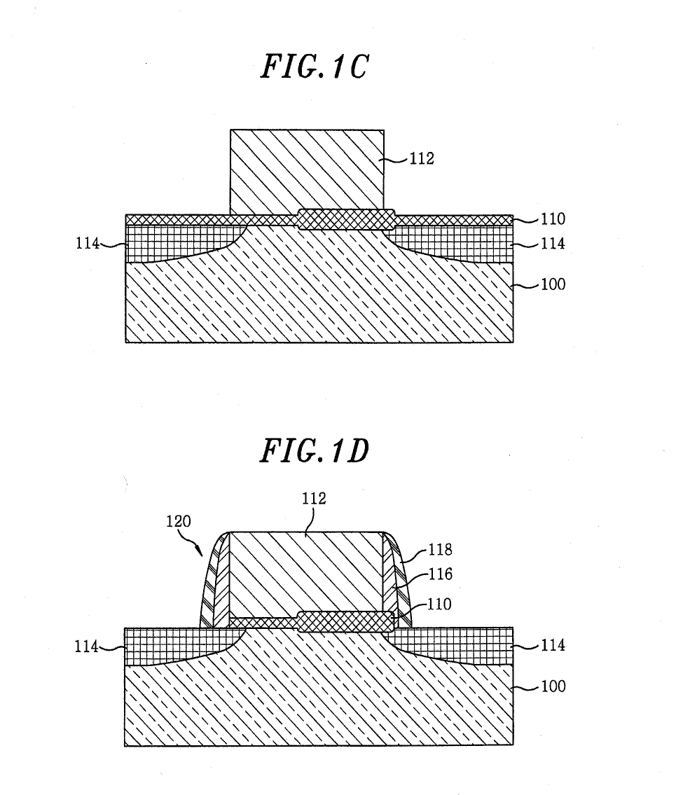

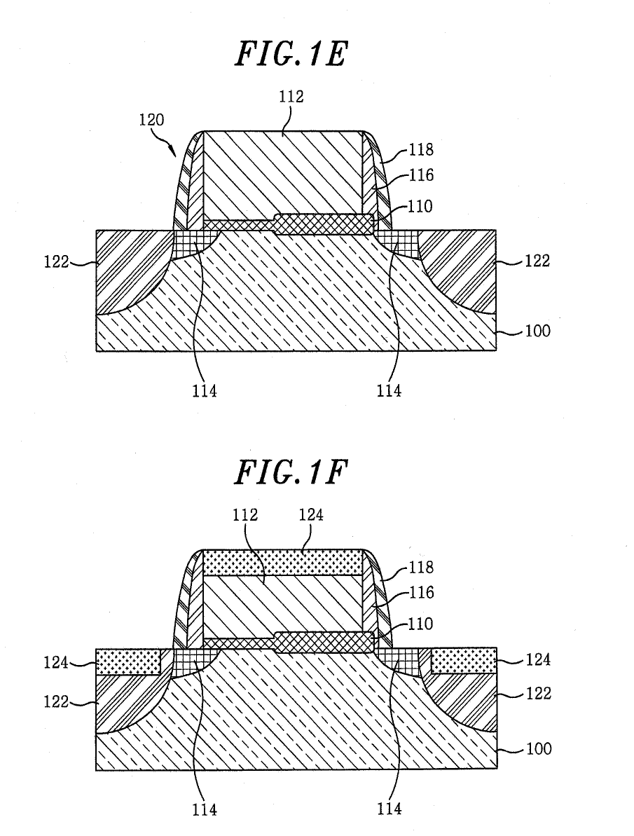

Example FIGS. 1A to 1F are process sectional views showing a method of manufacturing a semiconductor device according to embodiments.

### DESCRIPTION

Example FIGS. 1A to 1E are process sectional views showing a method of manufacturing a semiconductor device according to embodiments. Hereinafter, a process for manufacturing a semiconductor device according to embodiments will be described with reference to example FIGS. 1A to 1E.

First, as shown in example FIG. 1A, in a STI (Shallow Trench Isolation) forming step, F+(Fluorine) ions may be implanted into a 4.3-V power pad region on a semiconductor substrate 100 using a STI mask (formed by oxide film 102 and a silicon nitride film 104) so as to form an F+ ion layer 108.

Next, as shown in example FIG. 1B, the STI mask, including the oxide film 102 and the silicon nitride (SiN) film 104, may be removed, and then a gate oxide film 110 may be formed. When the gate oxide film 110 is formed, a dual gate oxide film 110 may be formed, in a portion (A2) of a poly gate region (A1), the poly gate region A1 defined as a region where a poly gate is to be formed. The dual gate oxide film 110 is thicker over the F+ ion layer 108 in the semiconductor substrate 100. The thickness is different from other regions due to F+ ions being implanted in advance. The gate oxide film has a relatively large thickness due to F+ ion implantation, and the thicker portion of the gate oxide film overlaps with about ½ to about ⅔ of the poly gate region (A1).

Next, as shown in example FIG. 1C, a polysilicon film may be formed over the semiconductor substrate 100 and patterned so as to form a poly gate 112. In this case, the poly gate 112 is formed such that the thick region (A2) of the gate oxide film 112 is disposed over the drain side. Low-concentration impurity ions are implanted into the semiconductor substrate 100 on both sides of the poly gate 112 so as to form LDDs (Lightly Doped Drains) 114.

Next, as shown in example FIG. 1D, a TEOS (tetraethyl orthosilicate) film 116 and a SiN film 118 are formed over the semiconductor substrate 100. The TEOS film 116 and the SiN film 118 may be etched back so as to form spacers 120 over both sidewalls of the poly gate 112.

Next, as shown in example FIG. 1E, impurity ion implantation may be performed so as to form source and drain regions 122 in active regions of the semiconductor substrate 100 near the spacers at both sidewalls of the poly gate 112. Thereafter, as shown in example FIG. 1F, salicidizing may be performed so as to form a silicide layer 124 at the upper parts of the poly gate 112 and the source and drain regions 122.

As described above, with the method of manufacturing a semiconductor device according to embodiments, fluorine ions may be implanted into a part of a region on the semiconductor substrate where the gate is to be formed such that a dual gate oxide film over a drain is formed so as to have a relatively large thickness. Thus, an electric field applied to the drain can be reduced, and HCI reliability can be improved when a 4.3-V power pad is used with a 3.3-V MOSFET. Further, fluorine ions may be implanted so as to form a dual gate oxide film below a gate region. Therefore, it is not necessary to perform an additional mask process for forming a dual gate oxide film, and to simplify a process for forming a dual gate oxide film.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
implanting fluorine ions into a portion of a poly gate region on a semiconductor substrate;
forming a gate oxide film over the semiconductor substrate such that the gate oxide film is thicker in the fluorine-implanted region;
forming the poly gate over the gate oxide film in the poly gate region;
forming lightly doped drains in active regions of the semiconductor substrate on both sides of the poly gate;
forming spacers over both sidewalls of the poly gate; and
forming source and drain regions in the active regions.

2. The method of claim 1, wherein the region where fluorine ions are implanted overlaps with about ½ to about ⅔ of the poly gate region.

3. The method of claim 1, wherein the fluorine-implanted region is formed toward the drain region of the semiconductor substrate below the gate oxide film.

4. The method of claim 1, wherein forming the spacers includes:
forming an insulating film over the entire surface of the semiconductor substrate having the poly gate formed thereon; and
etching back the insulating film to form the spacers over both sidewalls of the poly gate.

5. The method of claim 4, wherein the insulating film includes a TEOS film.

6. The method of claim 5, wherein the insulating film includes a SiN film.

7. The method of claim 1, including forming a silicide layer in the source and drain regions.

8. The method of claim 1, including forming a silicide layer in the upper portion of the poly gate.

9. An apparatus comprising:
a semiconductor substrate including a fluorine-implanted region overlapping a poly gate region;
an oxide film formed over a fluorine-implanted semiconductor substrate such that a gate oxide film has a relatively large thickness over the fluorine-implanted region;
a poly gate formed in the poly gate region over the gate oxide film;
lightly doped drains formed in active regions of the semiconductor substrate on the sides of the poly gate;
spacers formed over both sidewalls of the poly gate;
source and drain regions formed in the active regions.

10. The apparatus of claim 9, wherein the fluorine-implanted region overlaps with about ½ to about ⅔ of the poly gate region.

11. The apparatus of claim 9, wherein the fluorine-implanted region is formed toward the drain region of the semiconductor substrate below the gate oxide film.

12. The apparatus of claim 9, wherein the spacers are formed at both sidewalls of the poly gate by forming an insulating film over the entire surface of the semiconductor substrate having the poly gate formed thereon, and etching back the formed insulating film.

13. The apparatus of claim 12, wherein the insulating film includes a TEOS film.

14. The apparatus of claim 13, wherein the insulating film includes an SiN film.

15. The apparatus of claim 9, including a silicide layer in the source and drain regions.

16. The apparatus of claim 9, including a silicide layer in the upper portion of the poly gate.

17. An apparatus configured to:
implant fluorine ions into a portion of a poly gate region on a semiconductor substrate;
form a gate oxide film over the semiconductor substrate such that the gate oxide film is thicker in the fluorine-implanted region;
form the poly gate over the gate oxide film in the poly gate region;
form lightly doped drains in active regions of the semiconductor substrate on both sides of the poly gate;
form spacers over both sidewalls of the poly gate; and
form source and drain regions in the active regions.

18. The apparatus of claim 17, configured to the region where fluorine ions are implanted overlaps with about ½ to about ⅔ of the poly gate region.

19. The apparatus of claim 17, configured to form the fluorine-implanted region toward the drain region of the semiconductor substrate below the gate oxide film.

20. The apparatus of claim 17, configured to:
form an insulating film, including a TEOS film and an a SiN film, over the entire surface of the semiconductor substrate having the poly gate formed thereon; and
etch back the insulating film to form the spacers over both sidewalls of the poly gate.
